(19) United States
(12) Patent Application Publication
(10) Pub. No.: US 2022/0403504 A1
(43) Pub. Date: Dec. 22, 2022

(54) OPTICAL MONITORING DEVICE AND METHOD FOR CONTROLLING COATING THICKNESSES

(71) Applicant: Institute of Optics and Electronics, Chinese Academy of Sciences, Chengdu (CN)

(72) Inventors: Cunding LIU, Chengdu (CN); Ming LI, Chengdu (CN); Wei YANG, Chengdu (CN)

(21) Appl. No.: 17/840,501

(22) Filed: Jun. 14, 2022

(30) Foreign Application Priority Data
Jun. 21, 2021 (CN) 202110685733.3

(51) Int. Cl. C23C 14/54

(52) U.S. Cl. CPC C23C 14/547

(57) ABSTRACT

The disclosure relates to a device and method for coating thickness monitoring. The device comprises one or more lasers with different wavelengths, a light splitting optical element for beam splitting and beam combining of laser lights with different wavelengths, a diffuse plate, a driving motor, a lens, a multimode optical fiber, a light power meter, a test substrate and a coating fixture. The laser light is converted into partially coherent light through the rotating diffuse plate driven by a driving motor. The partially coherent light enters a multimode optical fiber through lens focusing, and is transmitted to a coating machine, collimated by a lens and then incident to a test substrate. The transmitted light enters a second multimode optical fiber after being focused by a lens, and is collimated and split at an optical fiber outlet. The light power meter is used for respectively measuring the power of the exiting light with different wavelengths and monitoring the transmissivities of lights with different wavelengths on the test substrate to realize the control of the coating thickness. The coating thickness monitoring device has the characteristics of simple structure, convenience in mounting, and narrow linewidth of the monitoring light source, and can realize the thickness control in a high-precision optical interference filter coating procedure.

### BACKGROUND

### Technical Field

The disclosure relates to the technical field of optical interference coatings, in particular to an optical monitoring device and method for controlling layer thicknesses in optical interference filters.

### Description of the Related Art

The optical interference filter is an optical element that can selectively modulate the reflectance and transmittance of light of different wavelengths through the optical interference in multi-layer coatings, and its performance is closely related to the thickness precision of sublayers which constitute the filter. Therefore, the high-precision control of the thicknesses of thin films is the core technology for preparation of optical interference filters. Methods commonly used to control the thickness of the thin film at present include the quartz monitor method, time control method, and optical control method. The quartz monitor determines the thickness of the deposited film by the relationship between the oscillation frequency of the quartz crystal and the thickness of the thin film deposited on the quartz crystal. Because the position of the quartz crystal monitor is usually different from that of the optical filter, the deposited coating thickness on the substrate and the monitored thickness are generally different, making it not suitable for deposition of a precise optical filter. The time control method is mainly applied to a coating procedure with stable coating speed, such as in ion beam sputtering coating. But in the long-time coating procedure, due to the continuous use of an ion source, a target material, and the like, the coating rate is gradually changed such that the error in film thickness control is caused. The optical monitoring method directly measures the film thickness on the surface of the optical filter by using optical signals, can directly control the performance of the optical filter, carries out real-time film thickness compensation, and is suitable for deposition of various optical interference filters.

At present, the optical monitoring device for thin film thickness is usually realized by adopting a light source, the light source is prepared into quasi-monochromatic light through a grating and a slit, and the light wavelength can be flexibly changed by adjusting the position of the slit. However, the optical monitoring device for thin film thickness based on light source suffers from a series of disadvantages. Firstly, because the light intensity is small after monochromatization, a great noise is brought, and the misjudgment of a coating termination condition is caused; secondly, because structures such as gratings and monochromatic slits, and the like are widely applied to the system, the system is very complex, high in manufacturing cost and very strict in stability requirement; and in addition, the wavelength linewidth of the quasi-monochromatic light is usually 1 nm and/or above, and in some filter coatings with high requirements, the wide linewidth also brings monitoring errors.

### BRIEF SUMMARY

The disclosure proposes an optical monitoring device and method for controlling thicknesses of the layers in optical interference filters based on laser sources, which improve the stability and reliability of an optical monitoring device for controlling coating thickness by using the characteristics of large intensity and narrow linewidth of the laser source; in the coating procedure, the curve of the changing transmittance of the monitoring light on the test substrate along with the coating thickness is simulated in real time such that the numbers of the transmissivity extrema is accurately determined, the transmissivity at the end of layer deposition is calculated in real time to be taken as a parameter for controlling the termination of the layer, and the stability and the reliability of the film thickness control are improved.

The technical scheme of the disclosure is: an optical monitoring device for controlling coating thickness, comprising one or more lasers with different wavelengths, a light splitting element for beam splitting and beam combining of laser lights with different wavelengths, a diffuse plate, a driving motor, a first multimode optical fiber, a second multimode optical fiber, a light power meter, a test substrate and a coating fixture, wherein the coating fixture is provided with a light-transmitting through-hole and a hole for holding the test substrate;

Laser light emitted by the laser is combined through a first group of light splitting elements, the combined laser light irradiates a rotating diffuse plate driven by a driving motor to form partially coherent light, the partially coherent light is focused to an inlet end of the first multimode optical fiber through a first lens, the first multimode optical fiber transmits the partially coherent light to a coating machine, and after being collimated by a second lens, the partially coherent light is incident to the test substrate located in the coating machine, the transmitted light passing through the test substrate is focused by a third lens and enters the second multimode optical fiber, and then the transmitted light is collimated by a fourth lens at an outlet of the second multimode optical fiber, and enters different light power meters after beam splitting by a second group of light splitting elements.

In a further optimized scheme, the optical monitoring device for controlling coating thicknesses further comprises a lens group arranged between the laser and the first group of light splitting elements, wherein laser light emitted by the lasers is combined by the first group of light splitting elements after beam characteristics are adjusted by the one or more lens groups. According to the scheme, the beam characteristics of the laser light are adjusted by arranging a lens group such that the size of the light spot and the divergence angle of the laser light spot are suitable for transmission, which is to the benefit of improving the precision of coating thickness control.

Further, the optical monitoring device for coating thickness further comprises one or more plane reflective elements for adjusting propagation direction of the light path. According to the scheme, the propagation direction of the light path is changed by arranging the plane reflective element such that the arrangement positions of each component can be optimized and the whole volume size of the device is thus reduced.

Further, the optical monitoring device for controlling coating thicknesses further comprises a diaphragm arranged between the diffuse plate and the first lens, wherein the partially coherent light is focused by the first lens to the inlet end of the first multimode optical fiber after passing through the diaphragm to shield unwanted stray light. According to the scheme, unwanted stray light is shielded by arranging the diaphragm such that the quality of the partially coherent light is further improved.

Further, the coating fixture rotates under the driving of a motor. Partially coherent light entering the coating machine respectively passes through the light-transmitting through-hole and the test substrate at different times, and for partially coherent light of any wavelength, I is light intensity passing through the test substrate measured by a corresponding light power meter, I₀ is the light intensity passing through the light-transmitting through-hole measured by the corresponding light power meter, and a transmissivity Tₘ of the test substrate at a corresponding wavelength is a ratio of I to I₀. The method for measuring the light intensity comprises the steps of setting a trigger threshold for the light power meter, starting recording the light intensity when the probed light intensity exceeds the trigger threshold, stopping recording the light intensity when the probed light intensity is lower than the trigger threshold, selectively recording an area of stable intensity in the middle of the recorded light intensity, and calculating the average light intensity as the measured light intensity I and I₀.

Further, for partially coherent light of any wavelength, the light intensity I passing through the test substrate and the light intensity I₀ passing through the light-transmitting through-hole are distinguished by comparing the light intensities measured by the light power meter, and during one rotation period of the coating fixture, a larger light intensity of the two light intensities corresponds to the light intensity I₀ passing through the light-transmitting through-hole, and the smaller light intensity corresponds to the light intensity I passing through the test substrate.

According to another aspect of the disclosure, the disclosure also proposes an optical monitoring method for controlling coating thicknesses. The method is realized based on the optical monitoring device mentioned above in the disclosure, and the method comprises steps below:
(1) simulating curves of changing transmissivity of the test substrate for laser light of different wavelengths along with the coating thicknesses in a coating procedure, and selecting the monitoring laser for each layer from at least two lasers of different wavelengths;
(2) before a coating is started, measuring transmissivity of the test substrate for laser light with different wavelengths, and calibrating the numerical value of the transmissivity to be the theoretical transmissivity of uncoated test substrate at the corresponding wavelengths;
and (3) starting film deposition, recording the transmissivity Tₘ of the test substrate to the monitoring laser light in the film deposition, calculating an actual thickness t of a deposited layer according to the curve of a changing transmissivity Tₘ along with the coating thickness, and calculating a derivative dTₘ/dt of the transmissivity Tₘ relative to a deposited layer thickness tin real time; when dTₘ/dt=0, recalculating actual refractive index of a coating layer at a monitoring laser light wavelength, the transmissivity T_{c} of the test substrate at the end of the coating, and the number of a transmissivity maximum value and the number of a transmissivity minimum value appearing in the coating procedure. When the numbers of the transmissivity maximum value and the transmissivity minimum value of the test substrate in the coating procedure respectively meet the requirement, and when Tₘ=T_{c}, terminating the layer coating.

When a deposited optical interference filter is a multi-layer film, the method further comprises steps below:
(4) carrying out back-calculation of the actual thickness of the deposited layer according to the curve of the changing transmissivity of the test substrate along with the film thickness, substituting the actual refractive index and the actual thickness of the layer into design of the interference filter, and recalculating a spectrum of the interference filter, wherein if the spectrum of the interference filter does not meet a design target, the thicknesses of the uncoated layers are optimized in real time to enable the spectrum of the interference filter to meet the design target;
(5) for the coating procedure using time monitoring as auxiliary monitoring, calculating an average coating rate according to the actual coating time and the actual coating thickness of the deposited layer; for the coating procedure using a quartz monitor as auxiliary monitoring, calculating a ratio of a monitored thickness of the quartz monitor to the actual coating thickness on the test substrate;
and (6) depositing a second to last sublayers by a same method as steps (3)-(5).

In step (1), based on the refractive indices of the layer materials and the refractive index of the test substrate, the curves of changing transmissivity of laser light on the test substrate along with the coating thicknesses are calculated for different laser wavelengths, and the laser light with the transmissivity of the test substrate before the end of the layer coating having one or more transmittance extrema, and the transmissivity of the test substrate at the beginning and the end of the layer coating having a maximum difference with theoretically calculated transmissivity maximum value and transmissivity minimum value is selected as a thickness monitoring laser light of the layer.

Further, for the layer that all the used laser light does not meet optical monitoring requirements, the layer thickness is controlled by coating time based on a recorded coating rate of a corresponding layer material, or through quartz crystal monitor based on a recorded ratio of the quartz crystal monitored thickness to the actual deposited thickness of a corresponding layer material, and the transmissivity curves of the test substrate under laser light of different wavelengths are recorded and taken as a basis for the back-calculation of the coating thickness and optical monitoring of the coating thickness of a subsequent layer.

Compared with a direct light control system adopting a light source at present, the disclosure has the technical advantages as follows.
The laser light source is adopted to provide a monochromatic light source, such that complex monochromatic mechanisms such as gratings, moving slits, and the like are avoided, the system is simpler, and the reliability is higher.
The adopted laser light source has high energy, realizes direct probe of beam power, and avoids weak signal extraction technologies such as phase-locked amplifying technology.
By adopting the multi-wavelength laser light source as a direct monitoring wavelength, the actual thickness of the thin film can be monitored and calculated in real time, such that the real-time optimization of the spectrum of the interference filter is realized.
The collection of the light control signals is obtained based on a trigger-collection-analysis procedure, such that the requirements of the rotation stability and rotation position detection accuracy of the coating machine are greatly reduced.

### BRIEF DESCRIPTION OF THE SEVERAL VIEWS OF THE DRAWINGS

In order to more clearly illustrate the technical solution of the embodiments of the disclosure, the following drawings which are required to be used in the embodiments will be briefly described. It should be understood that the following drawings illustrate only some embodiments of the disclosure and are therefore not to be construed as limiting the scope thereof. For a person skilled in the art without involving any inventive effort, other related drawings may also be obtained from these drawings.

FIG. 1 is a schematic view showing a structure of an optical monitoring device for controlling coating thicknesses provided in Embodiment 1;

FIG. 2 is a view showing a mounting structure of a test substrate and a through-hole in a vacuum chamber according to Embodiment 1 of the present disclosure;

FIG. 3 is a timing diagram of light intensity signal acquisition according to Embodiment 1;

FIG. 4 is a view showing a designed spectra of an optical interference filter according to Embodiment 2;

FIG. 5 is a graph showing a transmissivity of a 632.8 nm wavelength monitoring light changing with the coating time in a coating procedure according to Embodiment 2;

FIG. 6 is a graph showing the transmissivity of a 355 nm wavelength monitoring light changing with the coating time in the coating procedure according to Embodiment 2;

FIG. 7 is a graph showing the transmissivity of a 532 nm wavelength monitoring light changing with the coating time in the coating procedure according to Embodiment 2;

FIG. 8 is a schematic view of the transmissivity and transmissivity extrema when the coating terminates;

FIG. 9 is a schematic view for optimizing coating termination transmissivity in real time according to the transmissivity curve of a test substrate.

### DETAILED DESCRIPTION

The technical solutions in the embodiments of the present disclosure will be clearly and completely described below in conjunction with the accompanying drawings in the embodiments of the present disclosure. Obviously, the described embodiments are only a part of the embodiments of the present disclosure, rather than all the embodiments. The assembly of the embodiments of the disclosure generally described and illustrated in the drawings herein may be placed and designed in a variety of different configurations. Accordingly, the following detailed description of the embodiments of the disclosure provided in the accompanying drawings is not intended to limit the scope of the claimed disclosure, but merely represents selected embodiments of the disclosure. Based on the embodiments of the present disclosure, all other embodiments obtained by a technicist in the art without involving any inventive effort are within the scope of the present disclosure.

### Embodiment 1

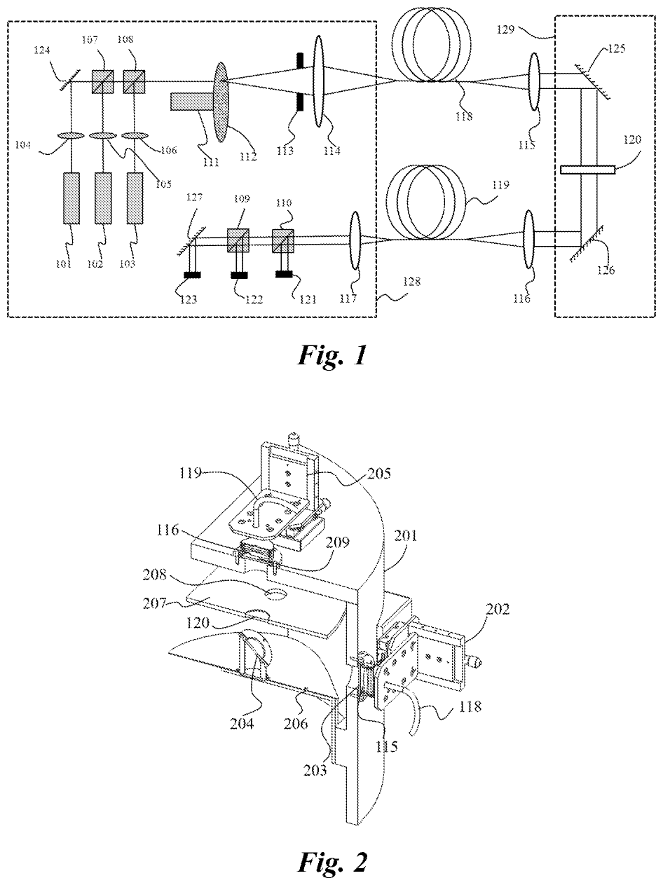

FIG. 1 shows a structure of an optical monitoring device for controlling coating thicknesses. The optical monitoring device for controlling coating thicknesses includes a first laser 101, a second laser 102 and a third laser 103 with three different wavelengths, a first lens group 104, a second lens group 105, and a third lens group 106, a first light splitting element 107, a second light splitting element 108, a third light splitting element 109, and a fourth light splitting element 110, a driving motor 111, a diffuse plate 112, a diaphragm 113, a first lens 114, a second lens 115, a third lens 116, and a fourth lens 117, a first multimode optical fiber 118 and a second multimode optical fiber 119, a test substrate 120, a first light power meter 121, a second light power meter 122, and a third light power meter 123, a first plane reflective element 124, a second plane reflective element 125, a third plane reflective element 126, and a fourth plane reflective element 127 which are selectively used for adjusting the transmission direction of a light path, a packaging box for an optical monitoring device 128, and a coating vacuum chamber 129 of a coating machine where the test substrate is located.

The first laser 101, the second laser 102 and the third laser 103, the first lens group 104, the second lens group 105, and the third lens group 106, the first light splitting element 107, the second light splitting element 108, the third light splitting element 109, and the fourth light splitting element 110, the driving motor 111, the diffuse plate 112, the diaphragm 113, the first lens 114 and the fourth lens 117, the first light power meter 121, the second light power meter 122, and the third light power meter 123, and the first plane reflective element 124, and the fourth plane reflective element 127 together form the main structure of the coating thickness optical monitoring device and are packaged inside the packaging box for an optical monitoring device for controlling coating thickness 128. Packaging box 128 has a shock absorption function to eliminate the influence of the vibration of a coating machine on a light path and isolate different optical components to avoid the influence of the stray light on the light power meters.

The first light splitting element 107 and the second light splitting element 108 realize the beam combination of lasers with different wavelengths, and the third light splitting element 109 and the fourth light splitting element 110 realize the beam splitting of lasers with different wavelengths.

The test substrate 120, the second lens 115 and the third lens 116, the second plane reflective element 125, and the third plane reflective element 126 are located on or in the vacuum wall of the coating vacuum chamber 129.

The first lens group 104, second lens group 105 and third lens group 106, the first lens 114, second lens 115, third lens 116 and fourth lens 117, and the first multimode optical fiber 118 and second multimode optical fiber 119 have high transmissivity at different laser wavelengths, and preferably, the surfaces of the lenses and the optical fibers are deposited with antireflective films for the laser wavelengths.

The test substrate 120 is a double-sided polished planar substrate, the prepared material thereof having high transmissivity at different laser wavelengths.

The diffuse plate 112 is made of a plane disk, having a high transmissivity at different laser wavelengths. The driving motor 111 drives the diffuse plate 112 to rotate around the center of the diffuse plate, and the embodiment adopts the disk having a diameter of 30 mm, and the rotation speed is greater than 100 rpm.

The working procedure of the optical monitoring device for controlling coating thicknesses is as follows: the laser lights emitted by the first laser 101, second laser 102, and third laser 103 respectively passes through the first lens group 104, second lens group 105, and third lens group 106 to adjust the beam spot size, divergence angle and other beam characteristics of the laser light, then are combined through the first light splitting element 107 and the second light splitting element 108; the combined multi-wavelength laser light is incident on the diffuse plate 112 which is driven to rotate by the driving motor 111; the rotating diffuse plate 112 converts the coherent laser light into partially coherent light, thereby attenuating the interference caused by reflected light from the laser light on different surfaces of the optical elements, particularly the interference of the reflected light on both surfaces of the test substrate 120. The transmitted partially coherent light is shielded from unwanted stray light by the diaphragm 113. Then the partially coherent light is converged by the first lens 114 and enters one end face of the first multimode optical fiber 118, is transmitted by the first multimode optical fiber 118 to the front of the second lens 115 fixed on the wall of the coating machine, is collimated by the second lens 115 and enters the coating machine, and is incident to the test substrate 120 perpendicularly or at a specific angle. Passing through the test substrate 120, the transmitted light, whose propagation direction is adjusted in the coating vacuum chamber 129 through the third plane reflective element 126, is focused by the third lens 116 into one end face of the second multimode optical fiber 119, is transmitted back to the inside of the packaging box for the optical monitoring device for controlling coating thicknesses 128, is collimated by the fourth lens 117 and decomposed by the third light splitting element 109 and the fourth light splitting element 110 into monochromatic light with different wavelengths, and enters the first light power meter 121, second light power meter 122 and third light power meter 123 respectively to probe the light intensity. The probed intensity of the transmitted light is input into a computer for analysis such that the control of the thickness coating is realized accordingly.

The first plane reflective element 124, second plane reflective element 125, third plane reflective element 126, and fourth plane reflective element 127 are selectively mounted in the light path to realize the adjustment of the propagation direction of the light beam.

FIG. 1 shows a basic structure of an optical monitoring device for implementing directly optical control. By adding elements to the system, the performance of the system can be improved. For example, noise caused by stray light and lights with other wavelengths can be reduced by adding an optical filter before a light power meter, etc.; the structural optimization of the system can be realized by optimizing the manufacturing mode of the element, such as adding a tapered light receiving device on the end face of the optical fiber to possibly increase the light collection efficiency, etc.; for another example, the laser lights emitted by each laser respectively realize partially coherent light and the like by using the diffuse plate rotating at a high speed; none of these additional components improves the underlying principles of the optical monitoring device for coating thickness and all of them are within the scope of the present disclosure.

FIG. 2 shows a mounting structure of an optical monitoring device for controlling coating thicknesses in a coating machine. Only the portion of the vacuum chamber wall 201 where the optical monitoring device for controlling coating thicknesses is mounted on is shown. 202 is a first three-dimensional adjustment mechanism for adjusting the relative positions of the first multimode optical fiber 118 and the second lens 115 such that the laser light exiting through the first multimode optical fiber 118 passes through the second lens 115 to become a parallel partially coherent light beam. The parallel partially coherent light beam is incident to the vacuum chamber through the incident optical window 203. After the propagation direction of the light beam is adjusted by the reflector 204, the parallel partially coherent light beam is incident to the test substrate 120 at a certain angle.

A second three-dimensional adjustment mechanism 205 is used for adjusting the position of the second multimode optical fiber 119 relative to the third lens 116.

In an embodiment, the light beam is incident to the test substrate perpendicularly. To avoid the influence of light generated by the coating procedure in the vacuum chamber, a reflector is mounted behind the baffle 206. The baffle 206 may also be used for adjusting the thickness uniformity of the coating at the same time.

The test substrate 120 is mounted on a coating fixture 207, and the light beam passes through the test substrate 120 for a certain time for every rotation around of the coating fixture.

The coating fixture 207 is further provided with a light-transmitting through-hole 208. After the light beam passes through the test substrate 120 in the coating procedure, the coating fixture 207 rotates at a certain angle again, and the light beam passes through the light-transmitting through-hole 208.

The transmitted light beam passing through the test substrate 120 and the light-transmitting through-hole 208 passes through the exiting optical window 209 and the third lens 116 and then is focused into the second multimode optical fiber 119, and is transmitted into a detector by the second multimode optical fiber 119. The ratio of the light intensity passing through the test substrate and the light intensity passing through the through-hole is measured and the transmissivity of the test substrate is calculated.

Preferably, the normal directions of the incidence optical window 203 and the exiting optical window 209 respectively have a certain angle with the incident angle of the light beam so as to avoid the influence of multiple reflections of the light beam on the surface of the window on the stability of the optical signal.

Alternatively, the incidence optical window 203 and the exiting optical window 209 may be realized by directly fixing the lens to the coating machine vacuum wall 201, in which case the vacuum sealing connection of the lens and the metal vacuum chamber is realized by means of a rubber seal ring and the like.

The laser power (light intensity) of a wavelength probed by the light power meter after the laser passes through the light-transmitting through-hole 208 is I₀, the power of the wavelength laser after passing through the test substrate 120 is I, and then the real-time measured transmissivity Tₘ of the test substrate is:

$${T}_{m} = \frac{I}{{I}_{0}} .$$

The light intensity probing manner is as follows: along with the rotation of the coating fixture driven by the driving motor, the partially coherent light spot enter the areas where the through-hole 208 and the test substrate 120 are located sequentially, along with the area of the light spot passing through the through-hole and the test substrate gradually increasing, the probing energy increases, and when the light spot completely enter the areas where the through-hole 208 and the test substrate 120 are located, the probing energy is at a basically stable value; as the coating fixture continues to rotate, the light spot gradually moves away from the through-hole 208 and the test substrate 120, and the energy gradually decreases.

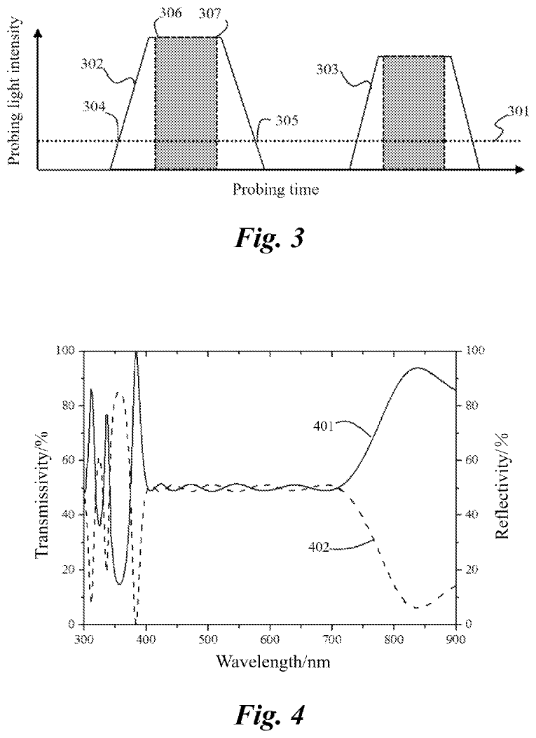

A schematic view of an optical energy probing procedure through the through-hole 208 and the test substrate 120 is shown in FIG. 3. A certain light energy 301 with a specific wavelength is selected as a trigger threshold. When the light energy is larger than the trigger threshold, the corresponding time is represented by 304, and the light power meter starts to record light intensity data. When the energy is weakened to be smaller than the trigger threshold, the corresponding time is represented by 305, indicating that the laser light leaves the area where the through-hole 208 or the test substrate 120 is located, and the light power meter stops recording the light intensity data. By analyzing the light intensity data from 304 to 305 time periods through software, the average light intensity in 306 and 307 time periods when the light intensity is stable is taken as the probed light intensity I or I₀.

In general, since the maximum transmissivity of the test substrate is smaller than the transmissivity of the through-hole, I and I₀ are judged through the light intensity. The large light intensity is the light intensity I₀ passing through the through-hole 208, as shown as 302 in FIG. 3; the weak light intensity is the light intensity I passing through the test substrate 120, as shown as 303 in FIG. 3. Therefore, the requirements for the rotating stability and the rotating position monitoring precision of the coating equipment are reduced.

It should be noted that the number of lasers is three in this embodiment, but there is practically no particular limitation on the number of lasers, and the number may be, for example, 1, 2, 4, or more.

### Embodiment 2

The following embodiment shows a method for realizing optical interference multi-layer film coating by performing coating thickness control using the optical monitoring device for controlling coating thicknesses. Taking Ta₂O₅ as the high refractive index material and SiO₂ as the low refractive index material, it should be noted that the high refractive index and low refractive index herein are only relative concept and do not limit a certain refractive index or range of refractive indices to a low refractive index or a high refractive index. The double-sided polished fused silica substrate serves as a test substrate to realize the function of the transmittance 401 and the reflectance 402 being close to 50% in a wavelength range of 400 nm-1000 nm as shown in FIG. 4. In the embodiment, only the working manner of the illustrated optical monitoring devices for controlling coating thicknesses is described, and various other film systems may be implemented by adopting the steps and the method herein.

The refractive indices of the Ta₂O₅ layer, the SiO₂ layer, and the double-sided polished fused silica substrate are represented by n_{H}, n_{L} and nₛ, respectively.

Three lasers are used with wavelengths of 632.8 nm, 355 nm, and 532 nm, respectively.

The film system is sub/100 nm H/59.92 nm L/75.94 nm H/130.45 nm L/39.92 nm H/80.63 nm L/166.6 nm H/63.57 nm L/39.29 nm H 126.87 nm L/air, where sub represents a fused silica substrate, H represents a high refractive index material Ta₂O₅, L represents a low refractive index material SiO₂, and air represents incident medium air.

In general, optical interference filter meeting specific spectral requirements can be realized by adopting different coating designs, and optical monitoring simulation of a coating procedure needs to be performed on different coating designs to select a design suitable for the monitoring wavelengths. The selecting basis includes, but is not limited to situations as follows: firstly, the difference between the refractive index of the first layer and the refractive index of the test substrate is large (greater than a set threshold), and at least at one wavelength, the transmissivity of the test substrate has one or more transmissivity extrema along with the increase of the coating thickness; secondly, in terms of each layer, at least at one wavelength, the transmissivity of the test substrate has one or more transmissivity extrema along with the increase of the coating thickness; Thirdly, in the coating procedure of each layer, the change in transmissivity of the test substrate is as large as possible (larger than a set threshold); and fourthly, the transmissivity of the test substrate at the beginning and the end of the coating of each layer is different from the transmittance extrema of the layer as much as possible.

Preferably, a computer automatic program can be adopted to achieve automatic screening of the coating design that best meets the monitoring requirements.

According to one embodiment of the disclosure, in the optical monitoring method for controlling coating thicknesses, deposition the optical interference filters includes steps as follows:

(1) Simulating the curve of the changing transmissivity of the test substrate to laser light with different wavelengths along with the coating thickness in the coating procedure, and selecting the monitoring laser light of each layer from at least two laser lights with different wavelengths;
in the embodiment, the laser light wavelengths used are 632.8 nm, 355 nm and 532 nm, respectively. Based on the refractive indices of the high refractive index layer, the low refractive index layer, and the fused silica test substrate at the three wavelengths, the transmissivity of the test substrate changing along with the thickness of the layer are simulated, and the monitoring wavelengths of each layer is selected according to the simulation results.

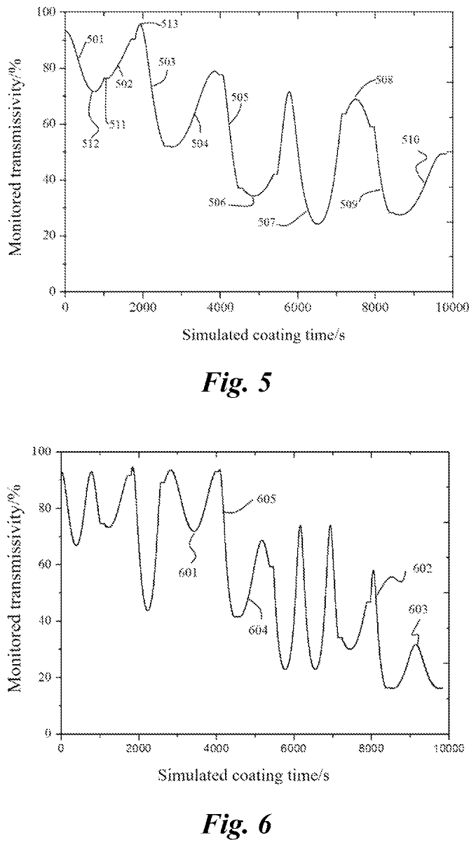

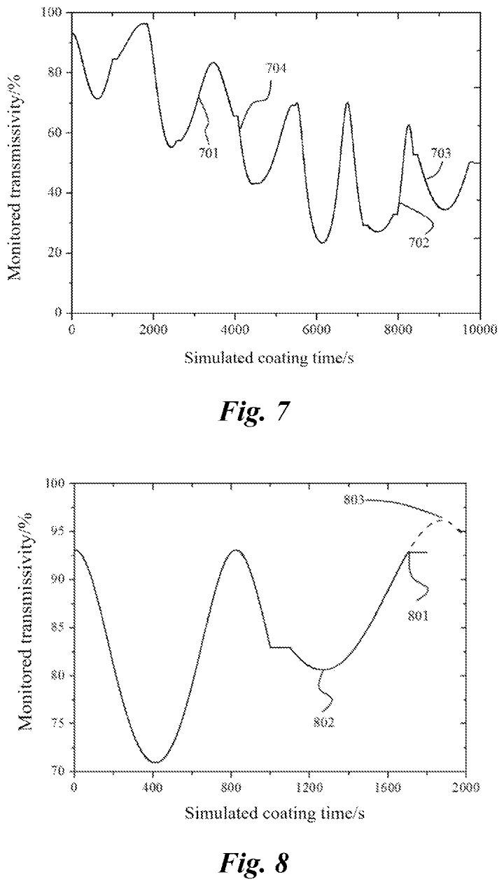

Considering that the deposition rate of each layer is 0.1 nm/s, the monitoring laser is at the wavelength of 632.8 nm, and the changing transmissivity of the test substrate along with the increase of the coating time is as shown in FIG. 5; at the wavelength of 355 nm, the changing transmissivity of the test substrate along with the increase of the coating time is as shown in FIG. 6; at the wavelength of 532 nm, the changing transmissivity of the test substrate along with the increase of the coating time is as shown in FIG. 7, where the abscissa is the simulated coating time and the ordinate is the transmissivity. Therefore, 501, 502, 503, 504, 505, 506, 507, 508, 509, and 510 in FIG. 5 respectively show the changing of the transmissivity of the test substrate along with the coating thickness when the 10 layers are sequentially deposited on the fused silica test substrate.

The monitoring laser light of each layer is selected according to the shown curves of the changing transmissivity of the test substrate along with the coating thickness. The selecting basis includes the situation as follows:
firstly, whether the transmissivity of the test substrate has an extremum as it increases along with the coating thickness in the layer deposition procedure or not, and if no extremum appears, the monitoring requirement is not met.

The transmissivity extremum indicates a transition point where the transmissivity becomes gradually smaller from gradually larger, or the transmissivity becomes gradually larger from gradually smaller, as shown at 512 in FIG. 5 as a transmissivity minimum value, and at 513 as a transmissivity maximum value. FIG. 5 shows that: when 632.8 nm laser light is used as the monitoring light, the transmissivity curves 502, 505, and 509 do not have transmissivity extrema, so the 632.8 nm laser source cannot be adopted as the monitoring light source for these layers; secondly, it is judged whether the changing value of the transmissivity along with the coating thicknesses in the depositing procedure of each layer meets the monitoring requirement or not, and if the changing value of the transmissivity in the depositing procedure of the layer is smaller than the monitoring requirement, the monitoring requirement is not met.

If it is defined that the minimum value of the transmissivity change meeting the monitoring requirement is 2%, the three laser light wavelengths meet the judgment basis as shown in FIGS. 5, 6, and 7.

Thirdly, the transmissivity of the layer at the beginning and at the end of the coating is greatly different from the transmissivity maximum value and the transmissivity minimum value of the layer.

FIG. 8 shows the relationship between the transmissivity 801 at the end of the coating of the second layer and transmissivity extrema 802 and 803 of the layer. One transmissivity extremum 802 appears during the deposition of the second layer; assuming that the coating thickness continues to increase, another transmissivity extremum 803 will appear, but the transmissivity extremum 803 will not appear during the coating procedure. However, when analyzing the monitoring wavelength of the layer, it must be ensured that the differences between the transmittance 801 and the transmissivity extrema 802 and 803 at the end of coating of each layer are both larger than a set threshold. The threshold is determined according to different coating designs and control precision, and in the embodiment, the threshold is set to 2%.

According to the judgment basis, the layers that can be monitored using a 632.8 nm wavelength laser light include 501, 506, 507, and 508.

In the curve of the changing transmissivity of the test substrate at the wavelength of 632.8 nm along with the coating thickness shown in FIG. 5, although the monitoring curves shown at 503 and 504 show the transmissivity extrema, the transmissivity of the coating termination point is very close to the transmissivity extrema, so 632.8 nm wavelength laser light are not suitable for monitoring the coating thickness of the two layers.

In the curve of the changing transmissivity of the test substrate at the wavelength of 355 nm along with the coating thicknesses shown in FIG. 6, although the transmittance monitoring curves of the fourth layer, the ninth layer, and the tenth layer, as shown at 601,602 and 603, show transmissivity extrema, the transmissivity of the coating termination point is very close to the transmissivity extrema such that the 355 nm wavelength laser light is not suitable for monitoring the coating thicknesses of the layers; in the transmissivity curve of the test substrate in the deposition of the sixth layer thin film marked by 604, the transmissivity at the end of coating meets the monitoring requirement, but the transmissivity at the beginning of the coating is very close to the transmissivity extremum such that the 355 nm wavelength laser light is not suitable for monitoring coating thickness of the layer.

In the transmissivity curve of the test substrate corresponding to the 532 nm wavelength shown in FIGS. 7, 701, 702, and 703 show transmissivity curves of the fourth layer, the ninth layer, and the tenth layer, and the three layers can be monitored with a 532 nm wavelength laser light.

Therefore, the wavelengths of the thickness monitoring laser of the layers in the embodiment are respectively as follows: thicknesses of the first, second, and third layers are controlled by 355 nm wavelength laser light, thickness of the fourth layer is controlled by the 532 nm wavelength laser light, thickness of the sixth layer is controlled by the 632.8 nm wavelength laser light, thicknesses of the seventh and eighth layers are controlled by the 355 nm wavelength laser light, and thicknesses of the ninth and tenth layers are controlled by the 532 nm wavelength light. In the coating procedure of the fifth layer, with regard to the three laser light wavelengths, the curves of the changing transmissivity of the test substrate along with the coating thickness are respectively shown by 505, 605, and 704. None of the laser meets the optical control requirements. Therefore, the thickness of the thin film is monitored in other manners such as time monitoring or quartz crystal monitoring.

(2) Before coating is started, the transmissivities of the test substrate to laser lights at different wavelengths are measured, and the numerical value of the transmissivity is calibrated to be theoretical transmissivity of the uncoated test substrate at the corresponding wavelengths;

the transmissivities of the test substrate to laser lights with different wavelengths are measured by adopting the 1device shown in FIG. 1, and when it is measured, the test substrate is positioned on a coating fixture in a vacuum chamber and moves along with the rotation of the coating fixture. After the light path shown in FIG. 1 is fixed, the transmissivity of the whole system is determined. The power of the through-hole transmission light is taken as 100%, and the power probed by the light power meter after passing through the test substrate is the transmissivity of the test substrate.

Generally, because of the influence of the thickness of the test substrate, the dispersion characteristics of the optical device, and the like, there is a certain difference between the actually measured and theoretically calculated transmissivity of the test substrate, and it is necessary to demarcate the actually measured transmissivity of the uncoated test substrate to be the theoretically calculated transmissivity of the uncoated test substrate. In the embodiment, the test substrate needs to be demarcated to have a transmissivity of 92.87% at 355 nm, 93.23% at 532 nm, and 93.31% at 632 nm.

(3) Starting layer deposition, recording the transmissivity Tₘ of the test substrate to the monitoring laser light in the layer depositing procedure, calculating the actual thickness t of the deposited layer according to the curve of the changing transmissivity Tₘ along with the coating thickness, and calculating the derivative dTₘ/dt of the transmissivity Tₘ of the test substrate relative to the layer thickness tin real time; when dTₘ/dt=0, the Tₘ is used for recalculating the actual refractive index of the coating material at the monitoring laser light wavelength, the transmissivity T_{c} of the test substrate at the end of the coating, and the numbers of the transmissivity maximum value and the transmissivity minimum value appearing in the coating procedure. When the numbers of the transmissivity maximum value and the transmissivity minimum value of the test substrate to the monitoring laser light in the coating procedure respectively meet the requirement, and when Tₘ=T_{c}, the layer coating terminates.

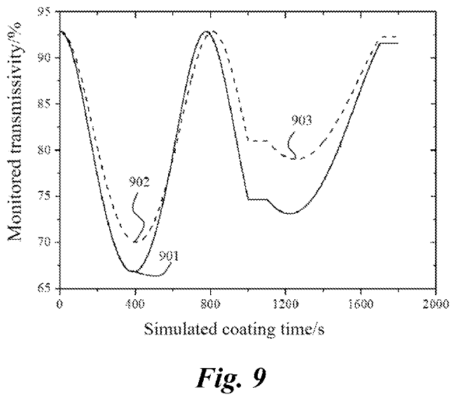

The first sublayer of the embodiment is a Ta₂O₅ thin film. FIG. 9 shows the difference between theoretically calculated transmittance of the test substrate (solid line) and the transmittance recorded during the actual coating procedure (dotted line) when there is a difference between the refractive index of the deposited Ta₂O₅ layer and the refractive index of the Ta₂O₅ layer used in film design. The transmissivity extremum of the first layer from design is shown as 901, and the transmissivity minimum value 902 appears along with the increase of the coating thickness in the coating procedure. When there is a difference between the refractive index of the actually deposited film and the refractive index of the film used in the film designing, there is a difference between the calculated transmittance minimum value 901 and the transmittance minimum value 902 obtained by actual monitoring.

In the embodiment, when the first layer is coated, the transmittance minimum value of the test substrate is determined by the refractive index of the deposited film and the refractive index of the substrate. The transmissivity T(λ) of the test substrate at a wavelength A is calculated by the following formula when the light is incident perpendicular to the surface of the test substrate:

$$T ( λ ) = \frac{( 1 - {ρ}_{01} ) ( 1 - {ρ}_{12} )}{1 - {ρ}_{01} {ρ}_{12}}$$

where ρ₀₁ is the reflection of the coated surface of the test substrate, and ρ₁₂ is the reflection of the uncoated surface of the test substrate. When the refractive index of the vacuum n₀=1, the reflection of the uncoated surface is:

$${ρ}_{12} = {( \frac{1 - {n}_{s}}{1 + {n}_{s}} )}^{2}$$

At a transmissivity minimum value of 902, the reflection of the single-layer coated surface is:

$${ρ}_{01} = {( \frac{1 - {n}_{1}^{2} / {n}_{s}}{1 + {n}_{1}^{2} / {n}_{s}} )}^{2}$$

where nₛ is the refractive index of the substrate and n₁ is the refractive index of the first layer. Therefore, in the embodiment, the actual refractive index of the first layer material Ta₂O₅ in the embodiment can be calculated according to the transmissivity minimum value 902 of the test substrate during the coating procedure of the first layer.

When there is a difference between the refractive index of the deposited thin film and the refractive index of the thin film adopted in the film design, change in the coating termination condition T_{c} of the first layer can also be caused. The termination transmissivity T_{c}, the numbers of the transmissivity maximum value and the transmissivity minimum value appearing in the coating procedure can be calculated in real time according to the value of the first transmittance extremum.

(4) Back-calculation of the actual thickness of the layer according to the curve of the changing transmissivity of the test substrate along with the layer thickness is carried out, the actual refractive index and the actual thickness of the layer are substituted into the coating design, and the spectrum of the optical interference filter is recalculated. If the spectrum of the optical interference filter does not meet the requirement, the thicknesses of the uncoated layers are optimized in real time to enable the coating design to meet the coating spectrum requirement;

When there is a difference between the refractive index of the deposited layer and the refractive index of the layer adopted by the coating design, the spectrum of the optical interference filter can deviate from the design target. The thicknesses of the second and above layers can be optimized according to the actually determined refractive index and coating thickness of the layer, such that the coating spectrum meets the design target. After the layer thicknesses are optimized, the monitoring laser light of the uncoated layers is determined according to step (1) again, and the thickness control parameters of the uncoated layers, such as the numbers of the transmittance maximum and the transmittance minimum appearing in the coating procedure, and the terminating transmissivity T_{c} of the test substrate are respectively determined.

The closer the refractive index of the layer used in the coating design is to the refractive index of the actually deposited layer, the smaller the difference between the theoretically simulated transmittance of the test substrate and the transmittance of the test substrate in the actual coating procedure is, and the shorter the time required for re-optimizing the thicknesses of the multilayer is. Therefore, the refractive index dispersion coefficients of the high refractive index layer and the low refractive index layer need to be precisely determined before coating.

(5) For the coating procedure using time monitoring as auxiliary monitoring, the average coating rate is calculated according to the actual coating time and the actual thickness of the layer; for the coating procedure using the crystal quartz monitor as auxiliary monitoring, the ratio of the monitored thickness by crystal quartz monitor to the actual coating thickness is calculated according to the thin film thickness monitored by the crystal quartz monitor and the actual coating thickness;

(6) The second to the last layers are deposited by the same method as steps (3)-(5).

When the second to the last layers are deposited, the transmissivity of the test substrate can be calculated through a characteristic matrix method. The expression of the characteristic matrix M is:

M=M_{N}M_{N-1} . . . M₂M₁,

where in 1, 2, . . . N−1, N represents N layers sequentially deposited on a test substrate. When a light beam is incident normally to the test substrate, the characteristic matrix Mᵢ from the test substrate to the i^{th} layer of the vacuum is as follows:

$${M}_{i} = [ \begin{matrix}cos ( 2 π {n}_{i} {d}_{i} / λ ) & \frac{i}{{n}_{i}} sin ( 2 π {n}_{i} {d}_{i} / λ ) \\ {in}_{i} sin ( 2 π {n}_{i} {d}_{i} / λ ) & cos ( 2 π {n}_{i} {d}_{i} / λ )\end{matrix} ]$$

where nᵢ is the refractive index of the i^{th} layer of the thin films sequentially deposited on the test substrate, dᵢ is the physical thickness of the i^{th} layer of the optical interference filter, and λ is the wavelength of the monitoring light. Two variables B and C are introduced and let:

$$[ \begin{matrix}B \\ C\end{matrix} ] = M [ \begin{matrix}1 \\ {n}_{s}\end{matrix} ]$$

then the reflection factor ρ₀₁ is:

$${ρ}_{01} = {\vert \frac{B - C}{B + C} \vert}^{2}$$

and when the N^{th} layer represents the layer being deposited, the thicknesses and refractive indices of the layers represented by N−1, . . . 2, 1 have been determined by the corresponding coating procedure. The refractive index of the N^{th} layer of the thin film can be determined from the curve of the changing transmissivity of the test substrate along with the coating thickness of the N^{th} layer.

The method for determining the refractive index of the second layer in the coating procedure is: when the second layer is deposited, with the increase of the coating thickness, the actual transmissivity of the test substrate has an extremum 903. Calculate the transmissivity extremum of the test substrate by using the characteristic matrix method when the material of the second layer takes different refractive indices, When the transmissivity extremum of the layer is the same as the actually measured transmissivity extremum 903, the corresponding refractive index is taken as refractive index of the actually deposited second layer.

In the embodiment, the second layer material is the low refractive index layer material SiO₂.

When there is a difference between the actual refractive index of the second layer and the refractive index of the second layer adopted by the coating design, the spectrum of the optical interference filters can deviate from the design target. The thickness of the third and above layers can be optimized according to the actually determined refractive indices and coating thicknesses of the first layer and the second layer, such that the coating spectrum meets the design target. After the layer thicknesses are optimized, the monitoring laser light wavelengths of the uncoated layers are selected according to step (1) again, and the thickness control parameters of the uncoated layers, such as the numbers of the transmittance maximum value and the transmittance minimum value appearing in the coating procedure, and the terminating transmissivity T_{c} of the test substrate when the coating terminates, are respectively determined.

In the coating procedure, the method for determining the refractive indices of the third and above layers is the same as the method for determining the refractive index of the second layer.

The method for determining the transmissivity extremum in the coating procedure is: simulating the curve of the changing transmissivity of the test substrate along with the coating thickness in real time, calculating the derivative dTₘ/dt of the transmittance relative to the coating thickness by using a theoretically simulated result, and determining the point corresponding to dTₘ/dt=0 from simulation result to be the transmittance extremum, thereby reducing the misjudgment on the extremum of the transmittance curve caused by the change of coating parameters such as short interruption of coating and light intensity noise.

In the coating procedure, for a layer that does not meet the optical thickness monitoring condition, time monitoring or crystal quartz monitoring is adopted to control the thickness of the thin film. The specific implementation method is: for a coating system with auxiliary control by a time control method, according to the average deposition rate calculated based on coating thickness and coating time of a previous layer of the same material, dividing the physical thickness of the layer by the average deposition rate to obtain a coating time, and monitoring the thickness of the thin film through the coating time; for the coating system with auxiliary control by the crystal quartz monitoring, according to a ratio between the thickness of the thin film on the test substrate and the recorded thickness of the crystal quartz monitor calculated based on the actual thickness and the monitored thickness of a previous layer of the same material, dividing the physical thickness of the layer to be deposited by the ratio to obtain the monitored thickness parameter of the layer, thereby controlling the thickness of the layer by using the crystal quartz monitoring.

In the coating embodiment, the fifth layer is monitored in the coating procedure by adopting the method, and the used average coating rate or the ratio between the actual coating thickness and the recorded thickness of the crystal quartz monitor adopts the data obtained when the third layer of the interference filter is coated.

When a standard Fabry-Perot filter is deposited, a laser with its wavelength the same as the center wavelength of the Fabry-Perot filter can be adopted as a monitoring light source in the coating procedure. The coating termination point is located at the transmissivity extremum, and the coating termination condition is determined by real-time monitored dTₘ/dt=0.

According to yet another embodiment of the present disclosure, optionally, the coating thickness control method of the embodiment of the present disclosure may also be implemented as computer software or a computer software program product. Moreover, the present disclosure may adopt the form of a computer program product implemented on one or more computer-usable storage media (including but not limited to disk storage, CD-ROM, optical storage, etc.) containing computer-usable program codes.

These computer program instructions may also be provided by the disclosure to a processor of a general purpose computer, special purpose computer, embedded processor, or other programmable data processing equipment to generate a machine such that the instructions are executed by the processor of the computer or other programmable data processing equipment to implement the method.

These computer program instructions may also be loaded onto a computer or other programmable data processing equipment to cause a series of operational steps to be executed on the computer or other programmable equipment to generate a computer implemented process such that the instructions, which are executed on a computer or other programmable equipment, can implement steps and functions specified in the method.

In an example configuration, the computing equipment includes one or more processors (CPUs), input/output interfaces, network interfaces, and memory. The memory may include volatile memory, random access memory (RAM), and/or non-volatile memory and like forms in a computer-readable medium, such as read only memory (ROM) or flash RAM. Memory is an example of a computer-readable medium.

Computer readable media, including both volatile and non-volatile, and mobile and non-mobile media, may implement information storage by any method or technique. The information may be computer readable instructions, data structures, modules of a program, or other data. Instances of storage media for a computer including, but being not limited to, phase change memory (PRAM), static random access memory (SRAM), dynamic random access memory (DRAM), other types of random access memory (RAM), read only memory (ROM), electrically erasable programmable read only memory (EEPROM), flash memory or other memory technologies, compact disk read only memory (CD-ROM), digital versatile disks (DVD) or other optical storage, magnetic cassettes, magnetic tape, and magnetic disk storage or other magnetic storage equipment, or any other non-transmission medium, can be used to store information which can be accessed by computing equipment. As defined herein, the computer-readable medium does not include transitory computer-readable media (transitory media), such as modulated data signals and carrier waves.

It is necessary to illustrate that the terms “include,” “comprise,” or any other variation thereof, are intended to cover a non-exclusive inclusion, such that a procedure, a method, a commodity, or equipment that includes a list of elements does not include only those elements but may include other elements not expressly listed or further include elements inherent to such procedure, method, commodity, or equipment. An element defined by the phrase “comprise one,” without more limitations, does not exclude the existence of additional identical elements in the procedure, method, commodity, or equipment that includes such elements.

It will be appreciated by those skilled in the art that embodiments of the present application may be provided as a method, system, or computer program product. Therefore, the present application may adopt the form of an entirely hardware embodiment, an entirely software embodiment, or an embodiment combining software and hardware aspects. Moreover, the present application may adopt the form of a computer program product implemented on one or more computer-usable storage media (including but not limited to disk storage, CD-ROM, optical storage, etc.) containing computer-usable program codes.

The above description is only specific preferred embodiments of the present disclosure, and the scope of the present disclosure is not limited thereto. It is within the scope of the disclosure that any person skilled in the art may readily conceive of alterations or substitutions within the technical scope of the disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An optical monitoring device for controlling coating thicknesses, comprising:
one or more lasers with different wavelengths;
a plurality of light splitting elements for beam splitting and beam combining of laser lights with different wavelengths;
a diffuse plate;
a driving motor;
a first multimode optical fiber;
a second multimode optical fiber;
a light power meter, a test substrate;
a first lens, a second lens, a third lens, and a fourth lens, and
a coating fixture,
wherein the coating fixture is provided with a light-transmitting through-hole and a hole for holding the test substrate; and
wherein in operation, laser light emitted by the lasers is combined through a first group of light splitting elements of the plurality of light splitting elements, the combined laser light irradiates a rotating diffuse plate driven by the driving motor to form partially coherent light, the partially coherent light is focused to an inlet end of the first multimode optical fiber through the first lens, the first multimode optical fiber transmits the partially coherent light to a coating machine, and after being collimated by the second lens, the partially coherent light is incident to the test substrate located in the coating machine, the transmitted light passing through the test substrate is focused by the third lens and enters the second multimode optical fiber, and then the transmitted light is collimated by the fourth lens at the outlet end of the second multimode optical fiber, and enters different light power meters after beam splitting by a second group of light splitting elements.

2. The optical monitoring device for controlling coating thicknesses according to claim 1, further comprising one or more lens groups arranged between the lasers and the first group of light splitting elements, wherein laser light emitted by the lasers is combined by the first group of light splitting elements after beam characteristics are adjusted by the one or more lens groups.

3. The optical monitoring device for controlling coating thicknesses according to claim 1, further comprising one or more plane reflective elements for adjusting propagation direction of light beams.

4. The optical monitoring device for controlling coating thicknesses according to claim 1, further comprising a diaphragm arranged between the diffuse plate and the first lens, wherein the partially coherent light is focused by the first lens to the inlet end of the first multimode optical fiber after passing through the diaphragm.

5. The optical monitoring device for controlling coating thicknesses according to claim 1, wherein the coating fixture rotates under a driving motor, partially coherent light entering the coating machine respectively passes through the light-transmitting through-hole and the test substrate at different times, and for partially coherent light of any wavelength, I is light intensity passing through the test substrate measured by a corresponding light power meter, I₀ is the light intensity passing through the light-transmitting through-hole measured by the corresponding light power meter, and a transmissivity Tₘ of the test substrate at a corresponding wavelength is a ratio of I to I₀.

6. The optical monitoring device for controlling coating thicknesses according to claim 5, wherein for partially coherent light of any wavelength, the light intensity I passing through the test substrate and the light intensity I₀ passing through the light-transmitting through-hole are distinguished by comparing the light intensities measured by the light power meter, and during one rotation period of the coating fixture, a larger light intensity of the two light intensities corresponds to the light intensity I₀ passing through the light-transmitting through-hole, and the smaller light intensity corresponds to the light intensity I passing through the test substrate.

7. An optical monitoring method for controlling coating thicknesses using the optical monitoring device according to claim 1, the method comprising options of:
(1) simulating curves of changing transmissivity of the test substrate for laser light of different wavelengths along with the coating thicknesses in a coating procedure, and selecting the monitoring laser light for each layer from at least two lasers with different wavelengths;
(2) before a coating is started, measuring transmissivity of the test substrate for laser light with different wavelengths, and calibrating the numerical value of the transmissivity to be the theoretical transmissivity of uncoated test substrate at the corresponding wavelengths;
(3) starting film deposition, recording the transmissivity Tₘ of the test substrate to the monitoring laser light in the film deposition, calculating an actual thickness t of a deposited layer according to the curve of a changing transmissivity Tₘ along with the coating thickness, and calculating a derivative dTₘ/dt of the transmissivity Tₘ relative to a deposited layer thickness tin real time; when dTₘ/dt=0, recalculating actual refractive index of a coating layer at a monitoring laser light wavelength, the transmissivity T_{c} of the test substrate at the end of the coating, and the number of transmissivity maximum value and the number of transmissivity minimum value appearing in the coating procedure. When the numbers of the transmissivity maximum value and the transmissivity minimum value of the test substrate in the coating procedure respectively meet the requirement, and when Tₘ=T_{c}, terminating the layer coating.

8. The optical monitoring method for controlling coating thicknesses according to claim 7, wherein when a deposited optical interference filter is a multi-layer film, the method further comprises operations of:
(4) carrying out back-calculation of the actual thickness of the deposited layer according to the curve of the changing transmissivity of the test substrate along with the film thickness, substituting the actual refractive index and the actual thickness of the layer into design of the interference filter, and recalculating a spectrum of the interference filter, wherein if the spectrum of the interference filter does not meet a design target, the thicknesses of the uncoated layers are optimized in real time to enable the spectrum of the interference filter to meet a coating spectrum requirement;
(5) for the coating procedure using time monitoring as auxiliary monitoring, calculating an average coating rate according to the actual coating time and the actual coating thickness of the deposited layer; for the coating procedure using a quartz monitor as auxiliary monitoring, calculating a ratio of a monitored thickness of the quartz monitor to the actual coating thickness on the test substrate;
(6) depositing the second to the last sublayers by a same method as the operations (3)-(5).

9. The optical monitoring method for controlling coating thicknesses according to claim 7, wherein in operation (1), based on the refractive indices of the layer materials and the refractive index of the test substrate, the curves of changing transmissivities of laser light on the test substrate along with the coating thicknesses are calculated for different laser wavelengths, and the laser light corresponding to the wavelength with the transmissivity of the test substrate before the end of the layer coating having one or more transmittance extrema, and the transmissivity of the test substrate at the beginning and the end of the coating having a maximum difference with theoretically calculated transmissivity maximum value and transmissivity minimum value is selected as a thickness monitoring laser light of the layer.

10. The optical monitoring method for controlling coating thicknesses according to claim 8, wherein for the layer that all the used laser light does not meet optical monitoring requirements, the film thickness is controlled by coating time based on a recorded coating rate of a corresponding layer material, or through quartz monitor based on a recorded ratio of the quartz monitored thickness to the actual deposited thickness of a corresponding layer material, and the transmissivity curves of the test substrate under laser light of different wavelengths are recorded and taken as a basis for the back-calculation of the coating thickness and the optical monitoring of the coating thickness of a subsequent layer.
